(19) United States
(12) Patent Application Publication
(10) Pub. No.: US 2015/0016631 A1
(43) Pub. Date: Jan. 15, 2015

(54) DYNAMIC TAIL SHORTENING

(71) Applicant: Apple Inc., Cupertino, CA (US)

(72) Inventors: Clemens Homburg, Hamburg (DE); Chris Adam, Rellingen (DE)

(21) Appl. No.: 13/941,061

(22) Filed: Jul. 12, 2013

(51) Int. Cl. H03G 3/20

(52) U.S. Cl. CPC H03G 3/20
USPC 381/98

(57) ABSTRACT

Systems and methods for reducing the length of music data files having decaying sound patterns are provided. A system and method can include analyzing a music data file including an attack portion and a tail portion. A fadeout range can be associated with the music data file, and a cut threshold of the tail portion can be identified. A modified version of the music data file can be played back. The playback can include reducing sound levels of the music data file in accordance with the fadeout range and ending the playback when the cut threshold of the tail portion is reached.

### BACKGROUND

The present disclosure relates generally to music data processing and more particularly to reducing the length of music data files having decaying sound patterns.

Digital audio workstations (DAWs) can provide users with the ability to record, edit, and play back digital audio. For instance, many DAWs include a sampling functionality wherein a user can create a musical composition by arranging music data files such as audio samples using a graphical user interface (GUI) and/or MIDI controller (e.g., a keyboard). Audio samples can simulate the sound of a real musical instrument, and thus playing back an arrangement of such musical samples can simulate a live musical performance.

In some situations, DAWs fail to accurately simulate the experience of listening to a real musical instrument during playback. For instance, DAWs may provide a limited number of channels that are available at any given time for playing back audio samples. Thus, the number of samples that can be played back at the same time may be limited by the number of available channels. If the channel limit has been met, the playback of an additional sample may require that the DAW abruptly cut off a sample that is currently being played to make its channel available for the additional sample. This may sound artificial and unpleasant to a listener.

Many musical instruments are associated with a decaying sound pattern. For instance, striking a cymbal or plucking a guitar string may produce a sound pattern with an intensity that decays over time. When a sample that simulates such a decaying instrument is played back, the sample may still occupy its assigned channel for some period of time after the intensity of the sound pattern has reached an inaudible or negligible level.

### SUMMARY

Certain embodiments of the invention are directed to reducing the length of music data files having decaying sound patterns.

In some embodiments, a computing device can analyze a music data file that includes an attack portion and a tail portion. A fadeout range can be associated with the music data file, and a cut threshold of the tail portion can be identified. A modified version of the music data file can be played back such that the playback includes reducing sound levels of the music data file in accordance with the fadeout range and ending the playback when the cut threshold of the tail portion is reached.

In some embodiments, a hold threshold of the of the attack portion can be identified. In such embodiments, playing back the modified version of the music data file can further include beginning the reduction of the sound levels of the music data file in accordance with the fadeout range when the hold threshold of the attack portion is reached.

In some embodiments, the modified version of the music data file can be played back each time a playback of the music data file is initiated. In some embodiments, the music data file can be one of a plurality of music data files, and the modified version of the music data file can be played back if playback of the of the plurality of music data files requires a number of channels that exceeds a determined number of available channels.

In some embodiments, one or more of analyzing the music data file, associating the fadeout range, and identifying the cut threshold can be performed during the playback. In some embodiments, one or more of analyzing the music data file, associating the fadeout range, and identifying the cut threshold can be performed prior to the playback.

In some embodiments, an input can be received that corresponds to a selection of the fadeout range and the cut threshold. In some embodiments, an input can be received corresponding to a selection of the hold threshold. Further, in some embodiments, the fadeout range, cut threshold, and/or hold threshold can be automatically determined. For instance, the fadeout range, cut threshold, and/or hold threshold can be determined using one or more sound characteristics of a musical instrument associated with the music data file.

In some embodiments, the music data file can be a first music data file, and a second music data file can also be analyzed. The first and second music data files can be determined to be layered, and modified versions of the first and second music data files can be played back simultaneously. Playing back the modified versions of the first and second music data files can include ending the playback of the second music data file when the cut threshold of the tail portion of the first music data file is reached.

### BRIEF DESCRIPTION OF THE DRAWINGS

FIG. 1 illustrates a simplified diagram of a system that may incorporate one or more embodiments;

FIG. 2 illustrates a simplified diagram of a music data file including an attack portion and a tail portion according to some embodiments;

FIG. 3 illustrates a simplified diagram of associating a fadeout range with a music data file according to some embodiments;

FIG. 4 illustrates a simplified diagram of identifying a cut threshold of a tail portion of a music data file according to some embodiments;

FIGS. 5-6B illustrate simplified diagrams of identifying a cut threshold of a tail portion and associating a fadeout range according to some embodiments;

FIG. 7 illustrates a simplified diagram of identifying a hold threshold of an attack portion according to some embodiments;

FIG. 8 illustrates a simplified diagram of identifying a cut threshold and associating a fadeout range in the context of layered music data files according to some embodiments;

FIGS. 9-10 illustrate simplified flowcharts depicting methods of reducing the length of a music data file having a decaying sound pattern according to some embodiments;

FIG. 11 illustrates a simplified diagram of a distributed system that may incorporate one or more embodiments;

FIG. 12 illustrates a simplified block diagram of a computer system that may incorporate components of a system for reducing the length of a music data file having a decaying sound pattern according to some embodiments.

### DETAILED DESCRIPTION

In the following description, for the purposes of explanation, specific details are set forth in order to provide a thorough understanding of embodiments of the invention. However, it will be apparent that various embodiments may be practiced without these specific details.

Certain embodiments of the invention are directed to reducing the length of music data files having decaying sound patterns. For instance, in some embodiments, music data files (e.g., audio samples) corresponding to a simulated instrument (e.g., a drum kit) can be analyzed and shortened by a computing device. The music data files can correspond to various components of the drum kit, such as a hi-hat, snare, bass drum, ride cymbal, crash cymbal, one or more toms, and the like. In some embodiments, the music data files can be in an arrangement created using a digital audio workstation (DAW) such as Logic Pro® provided by Apple Inc. of Cupertino, Calif. When played back, the arrangement of music data files can simulate a live drum performance.

Many drum kit pieces can produce a decaying sound pattern. For instance, striking a ride cymbal can create a sound pattern with an initial “attack” portion having high amplitude sound levels followed by a “tail” portion having sound levels that decay over time. Thus, some or all of the music data files simulating the drum kit components can include such decaying sound patterns. A portion of the music data files may be “overlapping” such that when the arrangement is played back, some of the music data files are played back concurrently. In the context of a DAW, overlapping music data files may be assigned their own channel during playback.

In some embodiments, the computing device can shorten (i.e. reduce the playback length) of one or more of the music data files by “clipping” or “cutting” their tail portions. For instance, as described in further detail below, applying a cut threshold to the tail portion in combination with a fadeout range applied to some or all of a music data file can be used to reduce its length. In some embodiments, as also described in further detail below, a hold threshold can be further applied to delay application of the fadeout range and thus preserve the sound levels of the attack portion of the music data file.

Although music data files corresponding to a simulated drum kit are described above, this is not intended to be limiting. In embodiments of the invention, music data files corresponding to any simulated instrument with a decaying sound pattern can be analyzed and shortened. For instance, in some embodiments, exemplary instruments can include stringed instruments (e.g., a guitar, bass, piano, etc.), other percussion instruments (e.g., a gong, bell, etc.), or any other suitable instrument with a decaying sound pattern. In some embodiments, one or more of the music data files can be digital recordings of an instrument being played live. Moreover, in some embodiments, one or more music data files may not correspond to a particular instrument and may instead be a non-instrument audio sample that may include a decaying sound pattern.

By reducing the length of music data files, the number of concurrent files (i.e., voices) played back in an arrangement can be reduced. Thus, in the context of a DAW that includes a limited number of available channels, the abrupt cut-off of music data files that may occur when channel limits are reached can be minimized or eliminated. Moreover, the shortening of music data files can be accomplished in an unnoticeable manner. By using a cut threshold that ends playback of a music data file when the tail portion has reached an appropriate sound level, in combination with a fadeout range that smoothly and gradually reduces sound levels, the clipping of the tail portion can be inaudible to a listener. Further, by use of a hold threshold to delay application of the fadeout range, the sound levels of the attack portion can remain unaltered which can improve the inconspicuousness of the file length reduction.

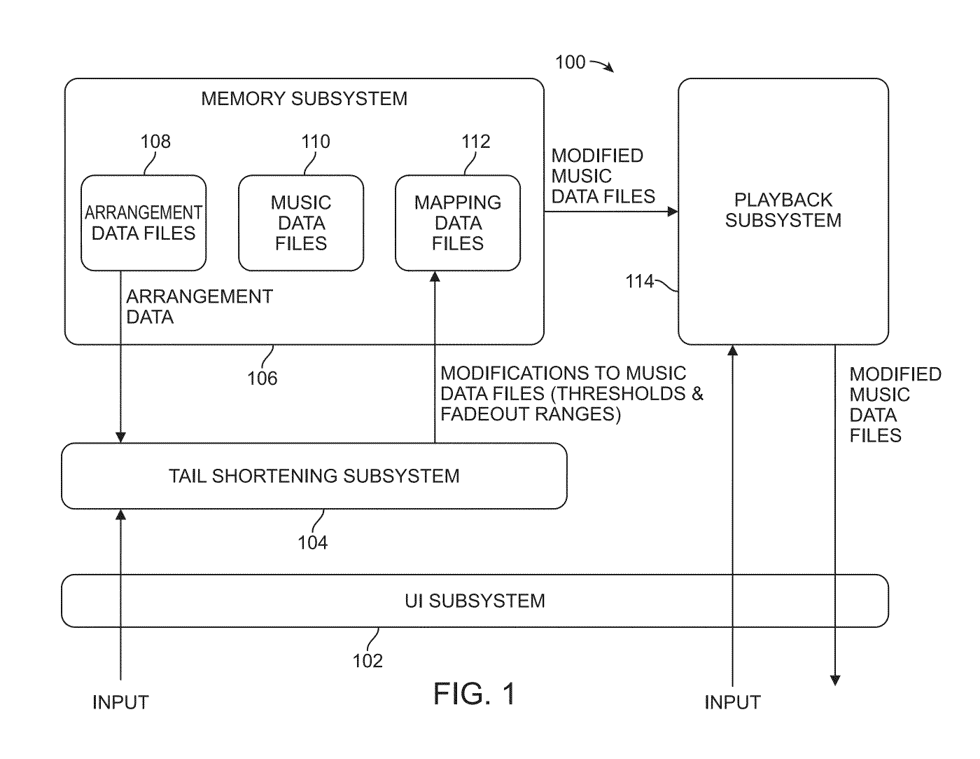

FIG. 1 illustrates a simplified diagram of a system 100 that may incorporate one or more embodiments of the invention. In the embodiment depicted in FIG. 1, system 100 includes multiple subsystems including a user interaction (UI) subsystem 102, a tail shortening subsystem 104, a memory subsystem 106 that stores arrangement files 108, music data files 110, and mapping data files 112, and a playback subsystem 114. One or more communication paths may be provided enabling one or more of the subsystems to communicate with and exchange data with one another. One or more of the subsystems depicted in FIG. 1 may be implemented in software, in hardware, or combinations thereof. In some embodiments, the software may be stored on a transitory or non-transitory medium and executed by one or more processors of system 100.

It should be appreciated that system 100 depicted in FIG. 1 may have other components than those depicted in FIG. 1. Further, the embodiment shown in FIG. 1 is only one example of a system that may incorporate one or more embodiments of the invention. In some other embodiments, system 100 may have more or fewer components than shown in FIG. 1, may combine two or more components, or may have a different configuration or arrangement of components. In some embodiments, system 100 may be part of a computing device. For instance, system 100 may be part of a desktop computer. In some embodiments, system 100 can be part of a mobile computing device such as a laptop computer, tablet computer, smart phone, media player, or the like.

UI subsystem 102 may provide an interface that allows a user to interact with system 100. UI subsystem 102 may output information to the user. For instance, UI subsystem 102 may include a display device such as a monitor or a screen. UI subsystem 102 may also enable the user to provide inputs to system 100. In some embodiments, UI subsystem 102 may include a touch-sensitive interface (i.e. a touchscreen) that can both display information to a user and also receive inputs from the user. For instance, in some embodiments, UI subsystem 102 can receive touch input from a user. Such touch input may correspond to one or more gestures, such as a drag, swipe, pinch, flick, single-tap, double-tap, rotation, multi-touch gesture, and/or the like. In some embodiments, UI subsystem 102 may include one or more input devices that allow a user to provide inputs to system 100 such as, without limitation, a mouse, a pointer, a keyboard, or other input device. In certain embodiments, UI subsystem 102 may further include a microphone (e.g., an integrated microphone or an external microphone communicatively coupled to system 100) and voice recognition circuitry configured to facilitate audio-to-text translation and to translate audio input provided by the user into commands that cause system 100 to perform various functions. In some embodiments, UI subsystem 102 may further include eye gaze circuitry configured to translate eye gaze input provided by the user into commands that cause system 100 to perform various functions.

Memory subsystem 106 may be configured to store data and instructions used by some embodiments of the invention. In some embodiments, memory subsystem 106 may include volatile memory such as random access memory or RAM (sometimes referred to as system memory). Instructions or code or programs that are executed by one or more processors of system 100 may be stored in the RAM. Memory subsystem 106 may also include non-volatile memory such as one or more storage disks or devices, flash memory, or other non-volatile memory devices. In some embodiments, memory subsystem 106 can store arrangement files 108, music data files 110, and mapping data files 112.

Music data files 110 stored in memory subsystem 106 can correspond to one or more simulated musical instruments. One or more of such instruments may be associated with a decaying sound pattern (e.g., a waveform including an initial attack portion and a decaying tail portion). In some embodiments, one or more of music data files 110 can be a digital recording of an instrument being played live. Further, in some embodiments, one or more of music data files 110 can be an audio sample that does not correspond to a particular instrument and that may include a decaying sound pattern. Music data files 110 can be in one or more audio formats including uncompressed formats (e.g., AIFF, WAV, AU, etc.), lossless compression formats (e.g., M4A, MPEG-4 SLS, WMA Lossless, etc.), lossy compression formats (e.g., MP3, AAC, WMA lossy, etc.), or any other suitable audio format.

Arrangement data files 108 stored in memory subsystem 106 can include arrangement data corresponding to a plurality of music data files 110. For instance, in some embodiments, a user can create a musical arrangement by arranging a plurality of music data files 110 within various tracks or channels using a graphical user interface (GUI) associated with a DAW executed by system 100. In some embodiments, one or more of music data files 110 can be arranged using an external controller (e.g., a MIDI keyboard). The arrangement data can identify which of music data files 110 are included in the arrangement. In some embodiments, the arrangement data can further identify the tracks and temporal positions (e.g., zones) to which music data files have been assigned within the arrangement, relationships between music data files (e.g., groupings of drum kit components), effects applied to the music data files in the arrangement (e.g., reverb, chorus, compression, distortion, filtering, etc.), and other parameters of the music data files such as velocity, volume, pitch, and the like.

Mapping data files 112 stored in memory subsystem 106 can include mapping data that describes shortening parameters that can be applied to one or more of music data files 110 during playback of an arrangement. For instance, as described herein, the playback length of a music data file can be reduced by applying a cut threshold in combination with a fadeout range to the music data file. As further described herein, a hold threshold can also be applied to the music data file to preserve the sound levels of the attack portion when the music data file is to be shortened. In some embodiments, such parameters can be stored as mapping data in mapping data files 112. In other embodiments, shortening parameters can be stored as within arrangement data files 108, or can be directly applied as modifications to music data files 110.

In some embodiments, system 100 may be part of a computing device. For instance, the computing device can be a desktop computer or a mobile computing device such as a laptop computer, tablet computer, smart phone, media player, and the like. In some embodiments, memory subsystem 106 may be part of the computing device. In some other embodiments, all or part of memory subsystem 106 may be part of one or more remote server computers (e.g., web-based servers accessible via the Internet).

In some embodiments, UI subsystem 102, tail shortening subsystem 104, memory subsystem 106, and playback subsystem 114, working in cooperation, may be responsible for reducing the length of one or more of music data files 110. For instance, input provided by a user can be received at tail shortening subsystem 104 from UI subsystem 102. In some embodiments, the input may correspond to an instruction to shorten the length of one or more of music data files 110 to be played back in a particular arrangement. In some embodiments, the one or more of music data files 110 can correspond to a particular instrument (e.g., a drum kit including various components).

Upon receipt of the input, tail shortening subsystem 104 can access arrangement data files 108 stored in memory subsystem 106 to identify which of music data files 110 are included in the arrangement. Tail shortening subsystem 104 can then analyze the identified music data files to determine whether fadeout ranges and thresholds are to be applied to some or all of the analyzed music data files. As described in further detail below, cut threshold values, fadeout range values, and hold threshold values can be provided by a user or, in some embodiments, can be determined automatically by system 100. For a given music data file, tail shortening subsystem 104 can calculate the reduction of sound levels resulting from a selected fadeout range, and can identify the point at which the sound levels of the tail portion reach the selected cut threshold value. In some embodiments, tail shortening subsystem 104 can further identify the point at which the sound levels of the attack portion of the music data file reach the selected hold threshold value. The modifications (e.g., cut thresholds, fadeout ranges, and hold thresholds) to be applied during playback can be stored, for instance, in mapping data files 112.

In some embodiments, further input provided by a user can be received at playback subsystem 114 from UI subsystem 102. For instance, the further input can correspond to an instruction to playback the arrangement of music data files. Playback subsystem 114 can utilize the arrangement data stored in arrangement data files 108 in combination with the modifications to the music data files stored in mapping data files 112 to playback the arrangement. For a given music data file that is to be shortened, playback subsystem 114 can playback a modified version of the music data file in accordance with the modifications stored in mapping data files 112. For instance, music data file can be modified such that the sound levels are reduced in accordance with the fadeout range and the playback of the music data file is terminated when the cut threshold of the tail portion is reached. In some embodiments, if mapping data files 112 indicate that a hold threshold is to be applied, the reduction of sound levels in accordance with the fadeout range can begin when the hold threshold of the attack portion is reached. Playback subsystem 114 can utilize an audio output device (e.g., a speaker) of UI subsystem 102 to playback the arrangement including the modified versions of the music data files.

As described above, in some embodiments, thresholds and fadeout ranges can be associated with music data files (e.g., stored in mapping data files 112) prior to playback. In some embodiments, such modifications can be associated with music data files and applied during playback. For instance, input provided by a user can be received during playback of an arrangement, the input corresponding to an instruction to reduce the length of one or more of the music data files included in the arrangement. In such embodiments, tail shortening subsystem 104 and playback subsystem 114, working in cooperation, can associate and apply any of the modifications described herein during playback.

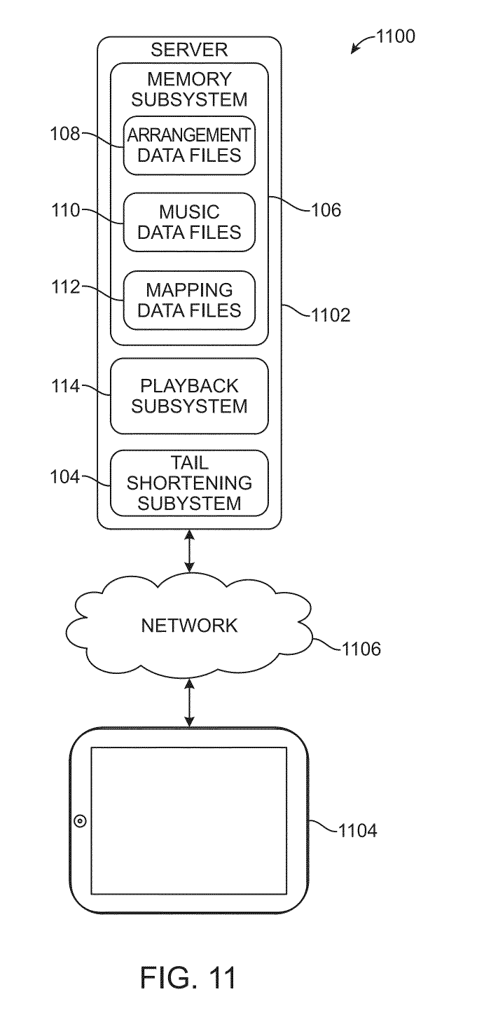

System 100 depicted in FIG. 1 may be provided in various configurations. In some embodiments, system 100 may be configured as a distributed system where one or more components of system 100 are distributed across one or more networks in the cloud. FIG. 11 illustrates a simplified diagram of a distributed system 1100 that may incorporate one or more embodiments of the invention. In the embodiments depicted in FIG. 11, tail shortening subsystem 104, playback subsystem 114, and memory subsystem 106 storing arrangement data files 108, music data files 110, and mapping data files 112 are provided on a server 1102 that is communicatively coupled with a computing device 1104 via a network 1106.

Network 1106 may include one or more communication networks, which can be the Internet, a local area network (LAN), a wide area network (WAN), a wireless or wired network, an Intranet, a private network, a public network, a switched network, or any other suitable communication network. Network 1106 may include many interconnected systems and communication links including but not restricted to hardwire links, optical links, satellite or other wireless communications links, wave propagation links, or any other ways for communication of information. Various communication protocols may be used to facilitate communication of information via network 1106, including but not restricted to TCP/IP, HTTP protocols, extensible markup language (XML), wireless application protocol (WAP), protocols under development by industry standard organizations, vendor-specific protocols, customized protocols, and others.

In the configuration depicted in FIG. 11, input provided by a user can be received at computing device 1104 and, in response, computing device 1104 can transmit the input (or data representing the input) to server computer 1102 via network 1106. The input can correspond to an instruction to reduce the length of one or more of music data files 110 to be played back in a particular arrangement. Upon receipt by server computer 1102, tail shortening subsystem 104 can analyze the music data files included in the arrangement as provided by arrangement data files 108. Modifications (e.g., thresholds and fadeout ranges) can be stored in mapping data files 112.

Further input provided by a user can be received at computing device 1104, the further input corresponding to an instruction to playback the arrangement of music data files. Computing device 1104 can transmit the further input (or data representing the further input) to server computer 1102 via network 1106. In response, playback subsystem 114 can utilize the arrangement data files 108, in combination with the modifications to the music data files as stored in mapping data files 112, to output a modified version of the arrangement. The modified version of the arrangement can be transmitted (e.g., streamed) by server computer 1102 to computing device 1104 via network 1106. In some embodiments, computing device 1104 can utilize an audio output device (e.g., a speaker) to playback the arrangement including the modified versions of the music data files as received from server computer 1102.

In the configuration depicted in FIG. 11, tail shortening subsystem 104, playback subsystem 114, and memory subsystem 108 are remotely located from computing device 1104. In some embodiments, server 1102 may facilitate the shortening of tail portions of music data files with decaying sound patterns, as described herein, for multiple computing devices. The multiple computing devices may be served concurrently or in some serialized manner. In some embodiments, the services provided by server 1102 may be offered as web-based or cloud services or under a Software as a Service (SaaS) model.

It should be appreciated that various different distributed system configurations are possible, which may be different from distributed system 1100 depicted in FIG. 11. The embodiment shown in FIG. 11 is thus only one example of a distributed system for reducing the length of music data files having decaying sound patterns and is not intended to be limiting.

As described herein, certain embodiments of the invention are directed to shortening (e.g., cutting the tail portions) of music data files having decaying sound patterns. The music data files can correspond to a simulated instrument such as a drum kit including various components that produce a decaying sound pattern. For instance, striking a cymbal or open hi-hat can produce a waveform that includes an initial “attack” portion having high amplitude sound levels followed by a “tail” portion having sound levels that decay over time.

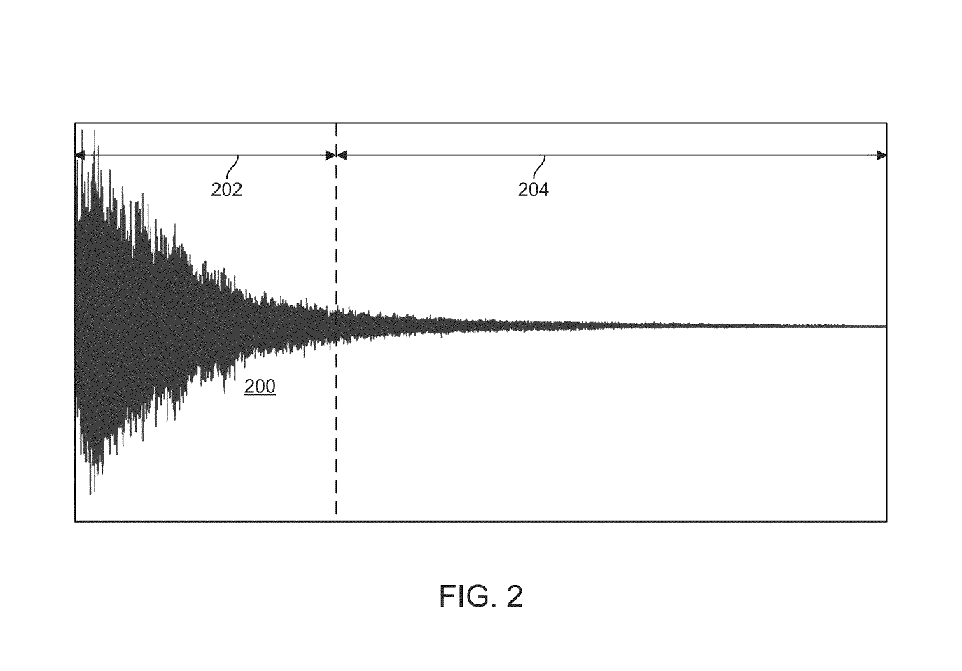

FIG. 2 illustrates a simplified diagram of a music data file including an attack portion and a tail portion according to some embodiments. As shown in FIG. 2, the music data file includes a sound pattern 200 (e.g., a waveform) that is depicted in terms of its intensity as a function of time. In FIG. 2, sound pattern 200 includes an attack portion 202 and a tail portion 204. The relative lengths of attack portion 202 and tail portion 204 can be determined in a number of different ways according to various embodiments. In some embodiments, attack portion 202 can include the time that elapses from the beginning of the music data file to the point where the peak sound level of sound pattern 200 occurs (i.e. the “attack time”). In such embodiments, tail portion 204 can include the time that elapses from the peak sound level to the end of the music data file or to the point of sound pattern 200 where the sound levels have decayed to nil or zero (i.e. the “decay time”). In the example depicted in FIG. 2, attack portion 202 and tail portion 204 are defined such that attack portion 202 includes the attack time in addition to a portion of the decay time, and tail portion 204 includes the remainder of the decay time. Thus, attack portion 202 includes the highest intensity peaks of sound pattern 200 that are most audible to a listener. The relative lengths of attack portion 202 and decay portion 204 can be determined or assigned in any suitable way according to various embodiments.

In some embodiments, a music data file can be shortened by applying a fadeout range in combination with a cut threshold to the music data file. For instance, the music data file can be analyzed from beginning to end such that a fadeout range is associated with all or a portion of the music data file and a cut threshold of the tail portion is identified.

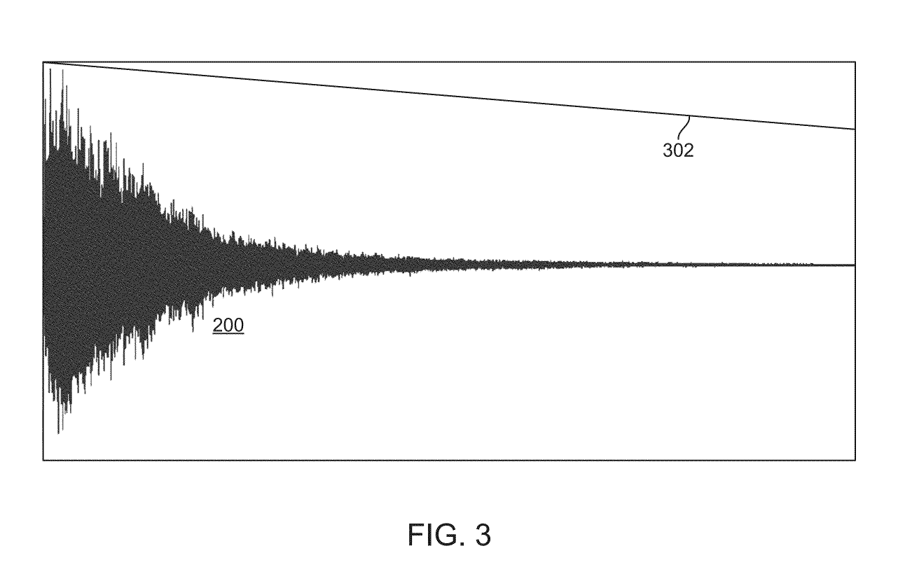

FIG. 3 illustrates a simplified diagram of associating a fadeout range 302 with a music data file according to some embodiments. In some embodiments, as depicted in FIG. 3, fadeout range 302 can cause a linear reduction of sound levels of the music data file by gradually reducing the amplitude of sound pattern 200 across the length of the music data file. As a non-limiting example, fadeout range 302 can be a linear fadeout range with a value of 15 dB. In this example, the sound level of the music data file can be reduced by 0 dB at the initiation point of the fadeout range and reduced by 15 dB at the end of the music data file. The sound levels from the initiation point to the end of the music data file can be reduced by linearly increasing values ranging from 0 dB to 15 dB. In some embodiments, as illustrated in FIG. 3, the initiation point of fadeout range 302 can be at the beginning of the music data file (e.g., the first data point of sound pattern 200). As described in further detail below, however, the initiation point can also be at some point in between the beginning and end of the music data file, such as at the end of attack portion 202 shown in FIG. 2. Further, in some embodiments, fadeout range 302 can cause a non-linear reduction of sound levels of the music data file.

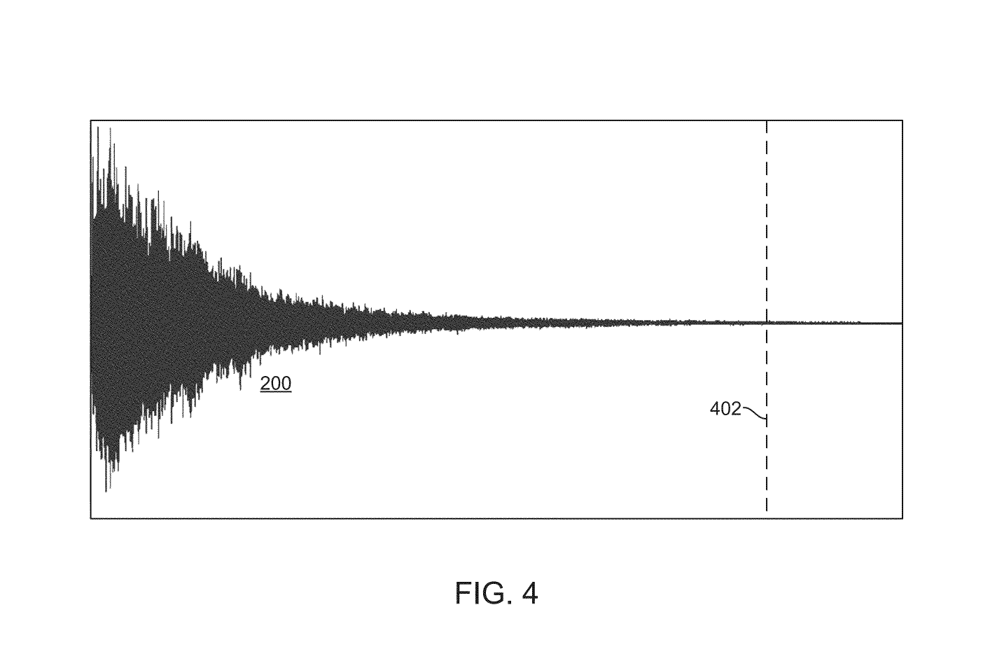

FIG. 4 illustrates a simplified diagram of identifying a cut threshold 402 of a tail portion of a music data file according to some embodiments. In some embodiments, cut threshold 402 can be used to clip the tail portion of the music data file such that playback of the music data file ends when cut threshold 402 is reached. As a non-limiting example, cut threshold 402 can be assigned a value of −80 dB. In this example, playback of the music data file can be terminated when the sound level (e.g., the amplitude of sound pattern 200) reaches a value of −80 dB relative to a reference sound level such as the peak value sound level (e.g., within attack portion 202 shown in FIG. 2) of sound pattern 200 or any other suitable reference value.

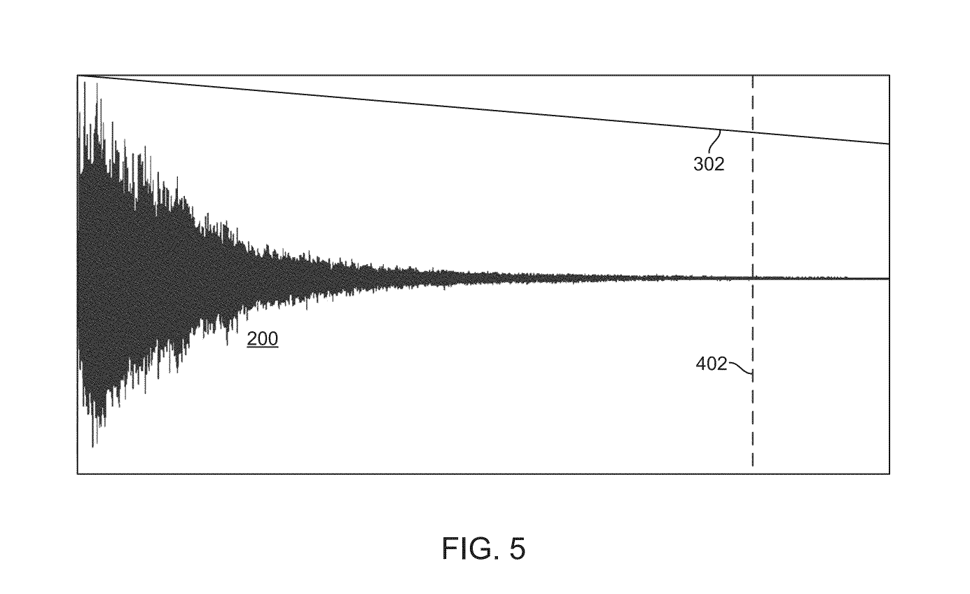

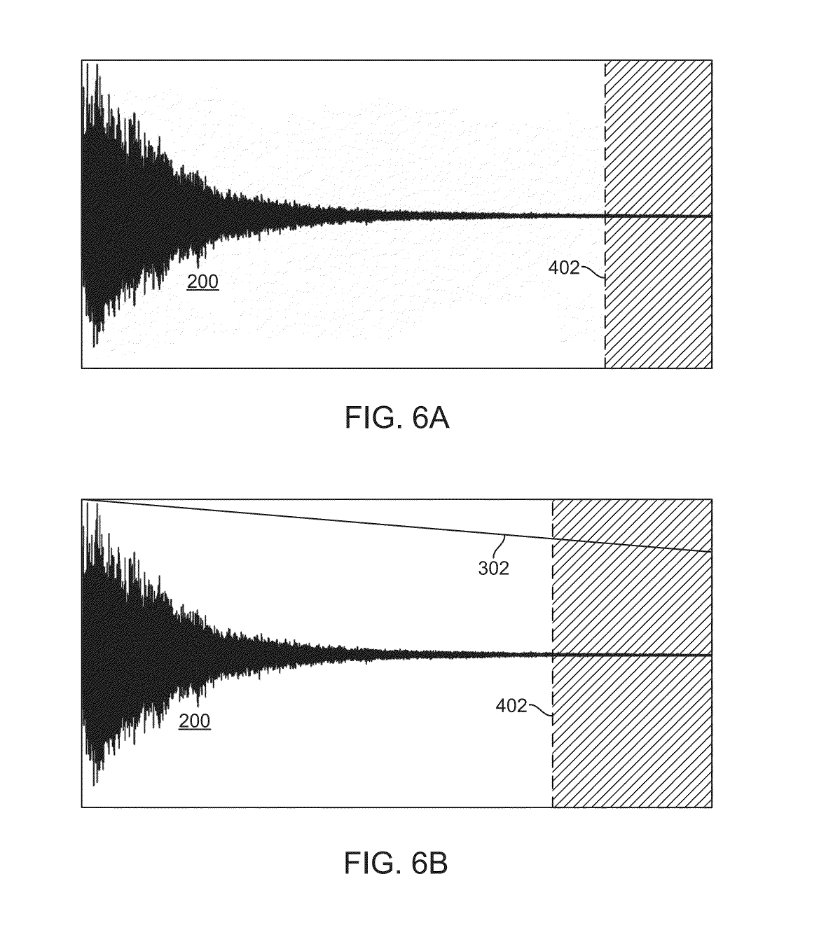

FIGS. 5-6B illustrate simplified diagrams of identifying a cut threshold of a tail portion and associating a fadeout range according to some embodiments. As illustrated in FIG. 5, fadeout range 302 and cut threshold 402 can be applied in combination to reduce the length of the music data file. In some embodiments, by applying the threshold range and cut threshold in combination, the length of the music data file can be reduced by a greater amount than if only the cut threshold is applied. For instance, as depicted in FIG. 6A, applying cut threshold 402 by itself may result in the length of the music data file to be reduced by a particular amount. As a non-limiting example, by applying cut threshold 402 with a value of −80 dB, the music data file can be reduced from an original length of 1.2 seconds to a shortened length of 1.0 seconds. If, however, a fadeout range is also applied, the length of the music data file can be further reduced.

As depicted in FIG. 6B, by applying cut threshold 402 in combination with fadeout range 302, cut threshold 402 can be reached “sooner” during playback of the music data file. As a non-limiting example, by applying cut threshold 402 with a value of −80 dB and fadeout range 302 with a value of 15 dB, the point on the decaying tail portion originally associated with a sound level of −65 dB can be reduced by 15 dB (i.e. the fadeout range value) to −80 dB (i.e. the value of cut threshold 402 in this example). Since playback of the music data file can be terminated at the original −65 dB position, the length of the music data file can be further reduced to a length of 0.66 seconds as an example.

In some embodiments, the initiation point of a fadeout range can be at some point in between the beginning and end of the music data file. For instance, a hold threshold of the attack portion (e.g., attack portion 202 shown in FIG. 2) can be identified and applied to the music data file such that during playback of the music data file, the reduction of sound levels caused by the fadeout range can begin when the hold threshold is reached.

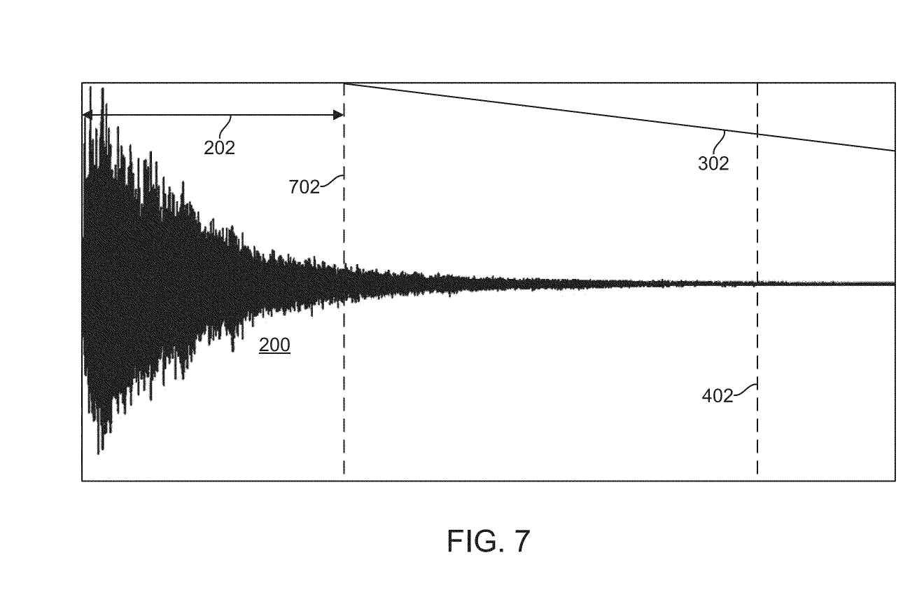

FIG. 7 illustrates a simplified diagram of identifying a hold threshold 702 of an attack portion according to some embodiments. Hold threshold 702 can be used to delay application of fadeout range 302 instead of applying fadeout range 302 from the beginning of the music data files. As a non-limiting example, hold threshold 702 can have a value of −20 dB. During playback of the music data file, the application of fadeout range 302 can be delayed until the sound level of the music data file (e.g., the amplitude of sound pattern 200) reaches −20 dB relative to a reference value such as the peak value sound level of attack portion 202 or any other suitable reference value. In such embodiments, hold threshold 702 can cause the sound levels of some or all of attack portion 202 to be unchanged by fadeout range 302.

In FIG. 7, hold threshold 702 is depicted as occurring at the end of attack portion 202 (e.g., the interface between attack portion 202 and tail portion 204 shown in FIG. 2). In some embodiments, hold threshold 702 can be assigned a value such that only a portion of attack portion 202 is unaffected by fadeout range 302. Further, in some embodiments, hold threshold 702 can be assigned a value such that all of attack portion 202 in addition to part of tail portion 204 are unaffected by fadeout range 302.

In some embodiments, cut thresholds and fadeout ranges can be applied to “layered” music data files. For instance, in an arrangement of music data files, two versions of the same music data file can be layered such that the files are played back simultaneously with an effect applied to one or both of the files.

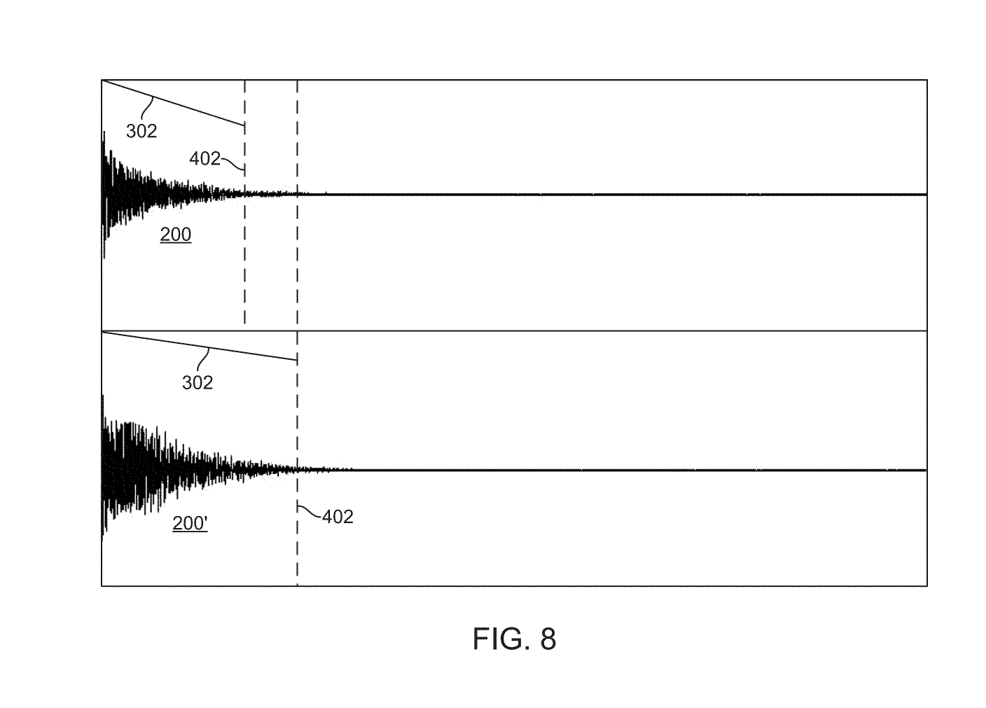

FIG. 8 illustrates a simplified diagram of identifying a cut threshold and associating a fadeout range in the context of layered music data files according to some embodiments. Sound pattern 200 shown in the top region of FIG. 8 can be sound pattern 200 depicted in FIGS. 2-7, and sound pattern 200′ shown in the bottom region of FIG. 8 can be sound pattern 200 depicted in FIGS. 2-7 but with an effect such as reverb applied. During playback of the music data files, fadeout range 302 and cut threshold 402 can both be applied to sound patterns 200, 200′. As further depicted in FIG. 8, the reverb effect applied to create sound pattern 200′ can cause the decay characteristics to change in comparison to sound pattern 200. Thus, the amplitudes of sound levels 200, 200′ may reach cut threshold 402 at a different points. In the example illustrated in FIG. 8, cut threshold 402 is reached “sooner” for sound pattern 200 in comparison to sound pattern 200′ with the reverb effect applies. Thus, during playback, the music data file including sound pattern 200 may be cut-off sooner than the layered music data file including sound pattern 200′. The mismatched cut-off may be audible to a listener.

In some embodiments, upon recognizing that the music data files are layered, the shortening of the music data files can be synchronized. For instance, as shown in FIG. 8, the later-occurring cut-off point for the music data file including sound pattern 200′ can also be applied to the music data file including sound pattern 200. In such embodiments, the music data file including sound pattern 200 will continue to playback until cut threshold 402 is reached by the music data file including sound pattern 200′. In some embodiments, the cut-off of the music data files can be synchronized with respect to the cut-off that occurs sooner such that the playback of the music data file including sound pattern 200′ is terminated when cut threshold 402 is reached by the music data file including sound pattern 200. In various embodiments, the above-described synchronization can be performed for any suitable number of layered music data files with any suitable applied effects.

The modification of music data files as illustrated in FIG. 2-8 and described above can be performed by a computing device. For instance, thresholds and fadeout ranges can be applied by a computing device including system 100 shown in FIG. 1. Such modifications can also be performed by any other suitable computing device incorporating any other suitable components according to various embodiments of the invention.

In some embodiments, the application of thresholds and fadeout ranges can be performed by a computing device in response to user input. For instance, via a GUI associated with a DAW running on the computing device, a user can provide input that causes the computing device to analyze an arrangement including a plurality of music data files. In some embodiments, the arrangement of music data files can correspond to a particular instrument such as a drum kit including various components. In response, the computing device can analyze the plurality of music data files to apply thresholds (e.g., cut thresholds and, in some embodiments, hold thresholds) in combination with fadeout ranges to one or more of the music data files. Such modifications can be stored, for instance, in mapping data files 112 of system 100 illustrated in FIG. 1. By storing the modifications in the form of mapping data files, the modifications can be applied during playback without altering the original music data files.

In some embodiments, the cut threshold values, fadeout range values, and hold threshold values applied by the computing device can be default values. For instance, the default values can be applied to music data files corresponding to a particular instrument. In some embodiments, a single set of default values can be applied to music data files corresponding to various components of an instrument (e.g., components of a drum kit). In some embodiments, different default values can be applied to music data files corresponding to different components. In some embodiments, the values can be dynamically determined by the computing device based on the sound characteristics of a musical instrument to which music data files correspond, such as the velocity, length of the tail portion, length of the attack portion, and any other suitable characteristic.

In some embodiments, the cut threshold values, fadeout range values, and hold threshold values can be provided and/or modified by the user via input provided to the computing device. For instance, via a GUI associated with a DAW running on the computing device, a user can adjust the threshold and fadeout range values for an entire arrangement of music data files, music data files corresponding to a particular instrument, music data files corresponding to individual components of an instrument, and individual music data files in some embodiments. In the case of music data files corresponding to a drum kit, for instance, a user can adjust the values for each component of the drum kit such as the bass drum, snare, one or more toms, hi-hat, crash cymbal, ride cymbal, etc. Input can also be provided by a user that causes the computing device to exclude one or more music data files from modifications. For instance, such input can cause the computing device to not apply thresholds or fadeout ranges to those music data files that correspond to a particular instrument or component, or to selected music data files. As a non-limiting example, since the waveforms of music data files that correspond to components such as a bass drum or tom typically do not include long tail portions, a user can provide input that causes the computing device to exclude such music data files from modification.

The synchronization of layered music data files can also be controlled via input provided by a user. For instance, such synchronization can be associated with an on/off setting that a user can select to control synchronization of layered music data files for entire arrangements, particular instruments, or components of an instrument. In some embodiments, the synchronization of layered music data files can be turned off or on as a default setting.

In some embodiments, music data files can be analyzed and modifications stored (e.g., in mapping data files 112 shown in FIG. 1) prior to playback of an arrangement including the music data samples. Upon analyzing the music data files (e.g., for a particular instrument) and storing the appropriate modifications, in some embodiments, the computing device can provide an indication to the user that summarizes the modifications made. For instance, a dialogue box can be displayed that provides information such as the threshold and fadeout range values that were applied, the amount of the music data files remaining and/or removed after shortening (e.g., provided as a percentage and/or a time measurement), the total number of music data files that were analyzed, the total number of attack portions and tail portions that were modified (e.g., by application of fadeout range(s)), the total number of tail portions that were clipped, the total number of unmodified attack portions and tail portions, the total number of attack portions including peak amplitudes below a threshold level, error messages, and any other suitable information describing the analysis and stored modifications.

As described above, in some embodiments, the analysis can be performed and modifications stored prior to playback of music data files. In some other embodiments, the analysis and/or modifications can be performed during playback of music data files. For instance, during playback of an arrangement, a user can provide input that modifies a threshold or fadeout range value, omits an instrument component, turns layered sample synchronization on/off, etc. In response, computing device can apply any modifications corresponding to the user input while the music data files are being played back. Such modifications can also be stored in mapping data files 112 shown in FIG. 1 for subsequent playback.

In some embodiments, instead of storing modifications in the form of mapping data files that can be accessed during playback, modifications can be applied directly to the stored music data files. For instance, thresholds and fadeout ranges can be applied to the music data file itself as stored on the computing device or at a remote storage location. In some embodiments, such modifications can also be stored in an arrangement file (e.g., in arrangement data files 108 shown in FIG. 1) such that parameters of the arrangement are directly modified but the music data files as stored are unchanged.

In some embodiments, a cut threshold, fadeout range, and/or hold threshold, can be applied each time a music data file is played back. In other embodiments, such modifications can be applied in scenarios when playback of an arrangement of music data files would result in the number of available channels being approached, reached, or exceeded. For instance, upon analyzing an arrangement of music data files, the computing device may determine that the number of channels required to play back the music data files exceeds a number of channels available to the computing device. In response, the computing device can shorten one or more of the music data files using thresholds and fadeout ranges as described herein.

By reducing the length of music data files, the number of simultaneously running “voices” can be reduced. Thus, in the context of a DAW that includes a limited number of available channels, the abrupt cut-off of music data files that may occur when channel limits are reached can be minimized or eliminated. Moreover, the shortening of music data files can be accomplished in an unnoticeable manner. By using a cut threshold that ends playback of a music data file when the tail portion has reached an inaudible or negligible sound level, in combination with a fadeout range that smoothly and gradually reduces sound levels, the clipping of the tail portion can be inaudible to a listener. Further, by use of a hold threshold to delay application of the fadeout range, the sound levels of the attack portion can remain unaltered which can improve the inconspicuousness of the file length reduction.

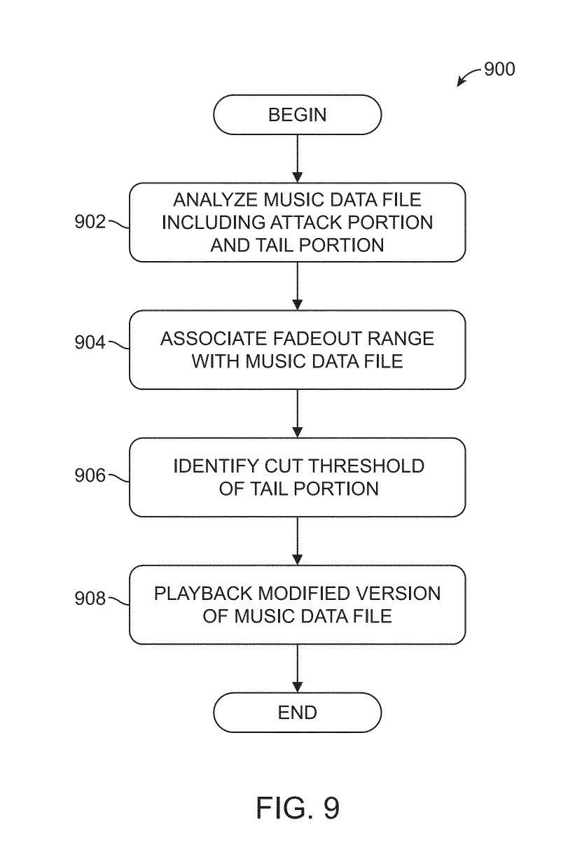

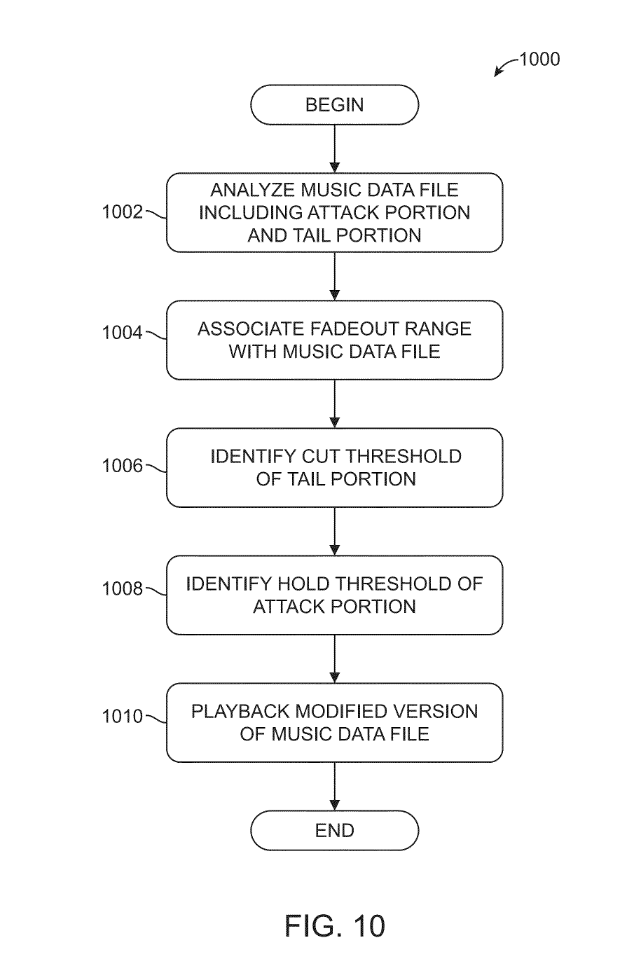

FIGS. 9-10 illustrate simplified flowcharts depicting methods 900, 1000 of reducing the length of a music data file having a decaying sound pattern according to some embodiments. The processing depicted in FIGS. 9-10 may be implemented in software (e.g., code, instructions, and/or a program) executed by one or more processors, hardware, or combinations thereof. The software may be stored on a non-transitory computer-readable storage medium (e.g., as a computer-program product). The particular series of processing steps depicted in FIGS. 9-10 are not intended to be limiting.

In particular, FIG. 9 illustrates a simplified flowchart depicting a method 900 of reducing the length of a music data file having a decaying sound pattern using a fadeout range in combination with a cut threshold.

As illustrated in FIG. 9, at step 902, a computing device can analyze a music data file including an attack portion and a tail portion. The music data file may correspond to a simulated instrument that has a decaying sound pattern (e.g., a cymbal, open hi-hat, gong, bell, guitar, bass, piano, etc.). In some embodiments, the music data file may be an audio recording of a live instrument performance and, in some embodiments, may instead be a non-instrument audio sample. The music data file can be in any suitable audio format such an uncompressed format, a lossless compression format, a lossy compression format, or any other suitable format.

At step 904, a fadeout range can be associated with the music data file. The fadeout range can cause a linear (or non-linear) reduction of sound levels of the music data file by gradually reducing the sound levels (e.g., the amplitude of the music data file's waveform) across all or part of the music data file. In some embodiments, the fadeout range can be stored in a mapping file or arrangement file that can be accessed when the music data file is played back. In some embodiments, the fadeout range can be directly applied such that the music data file as stored is modified.

At step 906, a cut threshold of the tail portion of the music data file can be identified. In some embodiments, the cut threshold can be used to clip or cut-off the tail portion of the music data file such that playback of the music data file is terminated when the sound level of the music data file reaches the cut threshold value. As with the fadeout range described above with respect to step 904, the cut threshold identified at step 906 can be stored in a mapping or arrangement file that can be accessed during playback, or can be applied directly to modify the music data file as stored.

At step 906, a modified version of the music data file can be played back. For instance, using the modifications stored in the mapping data files, a modified version of the music data file can be played back such that sound levels of the music data file are reduced in accordance with the fadeout range and the playback is ended when the cut threshold of the tail portion is reached.

FIG. 10 illustrates a simplified flowchart of depicting a method 1000 of reducing the length of a music data file having a decaying sound pattern using a fadeout range, cut threshold, and hold threshold.

In method 1000, steps 1002-1006 may be the same or similar to steps 902-906 of method 900 illustrated in FIG. 9. Thus, in some embodiments, further details regarding steps 1002-1006 are described throughout this disclosure, including in the above description of steps 902-906.

At step 1008, a hold threshold of the attack portion of the music data file can be identified. In some embodiments, the hold threshold can be used to delay application of the fadeout range until the sound level of the music data file (e.g., the amplitude of its waveform) decays to the hold threshold value. As with the fadeout range associated at step 1004 and the cut threshold identified at step 1006, the hold threshold identified at step 1008 can be stored in a mapping or arrangement file that can be accessed during playback, or can be applied directly to modify the music data file as stored.

At step 1010, a modified version of the music data file can be played back. For instance, using the modifications stored in the mapping data files, a modified version of the music data file can be played back such that, upon reaching the hold threshold, sound levels of the music data file are reduced in accordance with the fadeout range. Playback of the modified version of the music data file is ended when the cut threshold of the tail portion is reached.

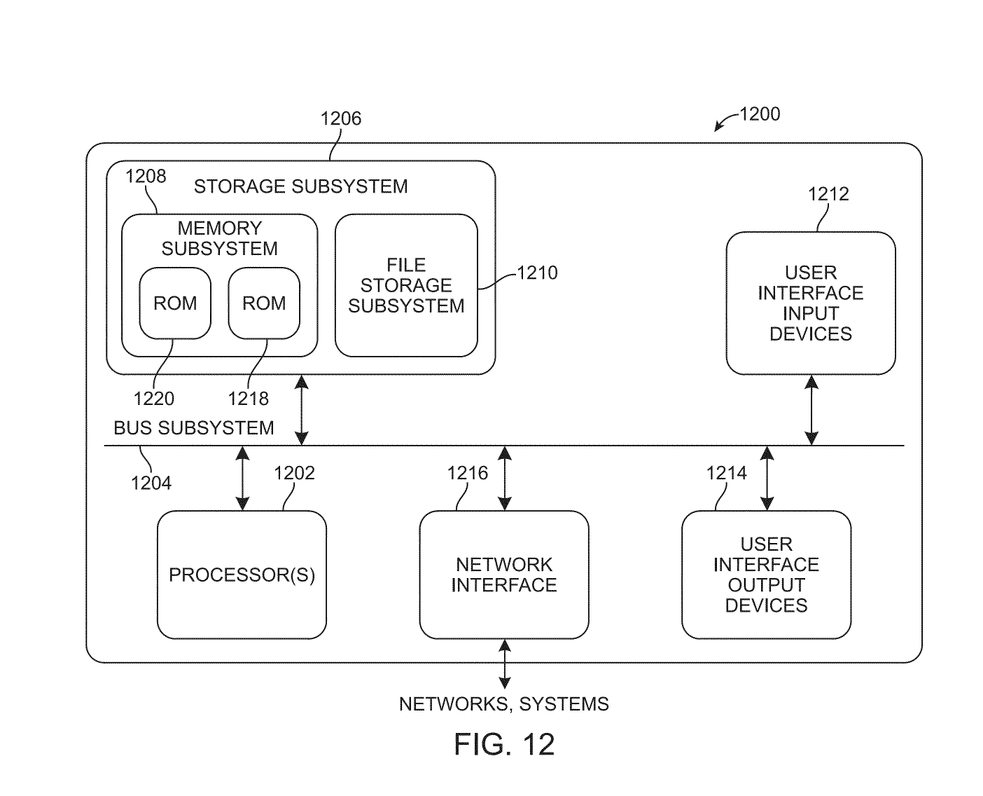

As described above, system 100 illustrated in FIG. 1 may incorporate embodiments of the invention. For instance, system 100 may shorten the tail portions of music data files with decaying sound patterns. System 100 may perform the various modifications to music data files as described above with respect to FIGS. 2-8, and/or may further provide one or more of the method steps described above with respect to FIGS. 9-10. Moreover, system 100 may be incorporated into various systems and devices. For instance, FIG. 12 illustrates a simplified block diagram of a computer system 1200 that may incorporate components of a system for reducing the length of music data files having decaying sound patterns in some embodiments. In some embodiments, a computing device can incorporate some or all the components of computer system 1200. As shown in FIG. 12, computer system 1200 may include one or more processors 1202 that communicate with a number of peripheral subsystems via a bus subsystem 1204. These peripheral subsystems may include a storage subsystem 1206, including a memory subsystem 1208 and a file storage subsystem 1210, user interface input devices 1212, user interface output devices 1214, and a network interface subsystem 1216.

Bus subsystem 1204 can provide a mechanism for allowing the various components and subsystems of computer system 1200 communicate with each other as intended. Although bus subsystem 1204 is shown schematically as a single bus, alternative embodiments of the bus subsystem may utilize multiple busses.

Processor 1202, which can be implemented as one or more integrated circuits (e.g., a conventional microprocessor or microcontroller), controls the operation of computer system 1800. One or more processors 1202 may be provided. These processors may include single core or multicore processors. In various embodiments, processor 1202 can execute a variety of programs in response to program code and can maintain multiple concurrently executing programs or processes. At any given time, some or all of the program code to be executed can be resident in processor(s) 1202 and/or in storage subsystem 1206. Through suitable programming, processor(s) 1202 can provide various functionalities described above.

Network interface subsystem 1216 provides an interface to other computer systems and networks. Network interface subsystem 1216 serves as an interface for receiving data from and transmitting data to other systems from computer system 1200. For example, network interface subsystem 1216 may enable computer system 1200 to connect to one or more devices via the Internet. In some embodiments network interface 1216 can include radio frequency (RF) transceiver components for accessing wireless voice and/or data networks (e.g., using cellular telephone technology, advanced data network technology such as 3G, 4G or EDGE, WiFi (IEEE 802.11 family standards, or other mobile communication technologies, or any combination thereof), GPS receiver components, and/or other components. In some embodiments network interface 1216 can provide wired network connectivity (e.g., Ethernet) in addition to or instead of a wireless interface.

User interface input devices 1212 may include a keyboard, pointing devices such as a mouse or trackball, a touchpad or touch screen incorporated into a display, a scroll wheel, a click wheel, a dial, a button, a switch, a keypad, audio input devices such as voice recognition systems, microphones, eye gaze systems, and other types of input devices. In general, use of the term “input device” is intended to include all possible types of devices and mechanisms for inputting information to computer system 1200. For example, in an iPhone®, user input devices 1212 may include one or more buttons provided by the iPhone® and a touchscreen which may display a software keyboard, and the like.

User interface output devices 1214 may include a display subsystem, indicator lights, or non-visual displays such as audio output devices, etc. The display subsystem may be a cathode ray tube (CRT), a flat-panel device such as a liquid crystal display (LCD), a projection device, a touch screen, and the like. In general, use of the term “output device” is intended to include all possible types of devices and mechanisms for outputting information from computer system 1200. For example, a software keyboard may be displayed using a flat-panel screen.

Storage subsystem 1206 provides a computer-readable storage medium for storing the basic programming and data constructs that provide the functionality of some embodiments. Storage subsystem 1206 can be implemented, e.g., using disk, flash memory, or any other storage media in any combination, and can include volatile and/or non-volatile storage as desired. Software (programs, code modules, instructions) that when executed by a processor provide the functionality described above may be stored in storage subsystem 1206. These software modules or instructions may be executed by processor(s) 1202. Storage subsystem 1206 may also provide a repository for storing data used in accordance with the present invention. Storage subsystem 1206 may include memory subsystem 1208 and file/disk storage subsystem 1210.

Memory subsystem 1208 may include a number of memories including a main random access memory (RAM) 1218 for storage of instructions and data during program execution and a read only memory (ROM) 1220 in which fixed instructions are stored. File storage subsystem 1210 may provide persistent (non-volatile) memory storage for program and data files, and may include a hard disk drive, a floppy disk drive along with associated removable media, a Compact Disk Read Only Memory (CD-ROM) drive, an optical drive, removable media cartridges, and other like memory storage media.

Computer system 1200 can be of various types including a personal computer, a portable device (e.g., an iPhone®, an iPad®, and the like), a workstation, a network computer, a mainframe, a kiosk, a server or any other data processing system. Due to the ever-changing nature of computers and networks, the description of computer system 1200 depicted in FIG. 12 is intended only as a specific example. Many other configurations having more or fewer components than the system depicted in FIG. 12 are possible.

Embodiments can be implemented in digital electronic circuitry, or in computer software, firmware, or hardware, including the structures disclosed in this specification and their structural equivalents, or in combinations of one or more of them. Embodiments of the subject matter described in this specification can be implemented as one or more computer program products, i.e., one or more modules of computer program instructions encoded on a non-transitory computer-readable medium for execution by, or to control the operation of, data processing apparatus.

Various embodiments described above can be realized using any combination of dedicated components and/or programmable processors and/or other programmable devices. The various embodiments may be implemented only in hardware, or only in software, or using combinations thereof. The various processes described herein can be implemented on the same processor or different processors in any combination. Accordingly, where components or modules are described as being configured to perform certain operations, such configuration can be accomplished, e.g., by designing electronic circuits to perform the operation, by programming programmable electronic circuits (such as microprocessors) to perform the operation, or any combination thereof. Processes can communicate using a variety of techniques including but not limited to conventional techniques for interprocess communication, and different pairs of processes may use different techniques, or the same pair of processes may use different techniques at different times. Further, while the embodiments described above may make reference to specific hardware and software components, those skilled in the art will appreciate that different combinations of hardware and/or software components may also be used and that particular operations described as being implemented in hardware might also be implemented in software or vice versa.

The various embodiments are not restricted to operation within certain specific data processing environments, but are free to operate within a plurality of data processing environments. Additionally, although embodiments have been described using a particular series of transactions, this is not intended to be limiting.

Thus, although specific invention embodiments have been described, these are not intended to be limiting. Various modifications and equivalents are within the scope of the following claims.

What is claimed is:

1. A computer-implemented method, comprising:
analyzing, by a computing device, a music data file including an attack portion and a tail portion;
associating a fadeout range with the music data file;
identifying a cut threshold of the tail portion; and
playing back a modified version of the music data file, wherein the playback includes reducing sound levels of the music data file in accordance with the fadeout range and ending the playback when the cut threshold of the tail portion is reached.

2. The method of claim 1, further comprising:
identifying a hold threshold of the attack portion, wherein the playback further includes beginning the reduction of the sound levels of the music data file in accordance with the fadeout range when the hold threshold of the attack portion is reached.

3. The method of claim 1, wherein the modified version of the music data file is played back each time a playback of the music data file is initiated.

4. The method of claim 1, wherein the music data file is one of a plurality of music data files, and wherein the modified version of the music data file is played back if playback of the of the plurality of music data files requires a number of channels that exceeds a determined number of available channels.

5. The method of claim 1, wherein one or more of the analyzing, associating, and identifying are performed during the playback.

6. The method of claim 1, wherein one or more of the analyzing, associating, and identifying are performed prior to the playback.

7. The method of claim 1, further comprising:
receiving an input corresponding to a selection of the fadeout range and the cut threshold.

8. The method of claim 1, further comprising:
automatically determining the fadeout range and the cut threshold sound level.

9. The method of claim 8, wherein the fadeout range and cut threshold are determined using one or more sound characteristics of a musical instrument associated with the music data file.

10. The method of claim 1, wherein the music data file is a first music data file, and wherein the method further comprises:
analyzing a second music data file;
determining that the first and second music data files are layered; and
simultaneously playing back the modified version of the first music data file and a modified version of the second music data file, wherein the playback includes ending the playback of the second music data file when the cut threshold of the tail portion of the first music data file is reached.

11. A computer-implemented system, comprising:
one or more data processors; and
one or more non-transitory computer-readable storage media containing instructions configured to cause the one or more processors to perform operations including:
analyzing a music data file including an attack portion and a tail portion;
associating a fadeout range with the music data file;
identifying a cut threshold of the tail portion; and
playing back a modified version of the music data file, wherein the playback includes reducing sound levels of the music data file in accordance with the fadeout range and ending the playback when the cut threshold of the tail portion is reached.

12. The system of claim 11, wherein the operations further include:
identifying a hold threshold of the attack portion, wherein the playback further includes beginning the reduction of the sound levels of the music data file in accordance with the fadeout range when the hold threshold of the attack portion is reached.

13. The system of claim 11, wherein the modified version of the music data file is played back each time a playback of the music data file is initiated.

14. The system of claim 11, wherein the music data file is one of a plurality of music data files, and wherein the modified version of the music data file is played back if playback of the of the plurality of music data files requires a number of channels that exceeds a determined number of available channels.

15. The system of claim 11, wherein one or more of the analyzing, associating, and identifying are performed during the playback.

16. The system of claim 11, wherein one or more of the analyzing, associating, and identifying are performed prior to the playback.

17. The system of claim 11, wherein the operations further include:
receiving an input corresponding to a selection of the fadeout range and the cut threshold.

18. The system of claim 11, wherein the operations further include:
automatically determining the fadeout range and the cut threshold sound level.

19. The system of claim 18, wherein the fadeout range and cut threshold are determined using one or more sound characteristics of a musical instrument associated with the music data file.

20. The system of claim 11, wherein the music data file is a first music data file, and wherein the operations further include:
analyzing a second music data file;
determining that the first and second music data files are layered; and
simultaneously playing back the modified version of the first music data file and a modified version of the second music data file, wherein the playback includes ending the playback of the second music data file when the cut threshold of the tail portion of the first music data file is reached.

21. A computer-program product, tangibly embodied in a non-transitory machine-readable storage medium, including instructions configured to cause a data processing apparatus to:
analyze a music data file including an attack portion and a tail portion;
associate a fadeout range with the music data file;
identify a cut threshold of the tail portion; and
play back a modified version of the music data file, wherein the playback includes reducing sound levels of the music data file in accordance with the fadeout range and ending the playback when the cut threshold of the tail portion is reached.

22. The computer-program product of claim 21, wherein the instructions are further configured to cause the data processing apparatus to:
identify a hold threshold of the attack portion, wherein the playback further includes beginning the reduction of the sound levels of the music data file in accordance with the fadeout range when the hold threshold of the attack portion is reached.

23. The computer-program product of claim 21, wherein the modified version of the music data file is played back each time a playback of the music data file is initiated.

24. The computer-program product of claim 21, wherein the music data file is one of a plurality of music data files, and wherein the modified version of the music data file is played back if playback of the of the plurality of music data files requires a number of channels that exceeds a determined number of available channels.

25. The computer-program product of claim 21, wherein one or more of the analyzing, associating, and identifying are performed during the playback.

26. The computer-program product of claim 21, wherein one or more of the analyzing, associating, and identifying are performed prior to the playback.

27. The computer-program product of claim 21, wherein the instructions are further configured to cause the data processing apparatus to:
receive an input corresponding to a selection of the fadeout range and the cut threshold.

28. The computer-program product of claim 21, wherein the instructions are further configured to cause the data processing apparatus to:
automatically determine the fadeout range and the cut threshold sound level.

29. The computer-program product of claim 28, wherein the fadeout range and cut threshold are determined using one or more sound characteristics of a musical instrument associated with the music data file.

30. The computer-program product of claim 21, wherein the music data file is a first music data file, and wherein the instructions are further configured to cause the data processing apparatus to:
analyze a second music data file;
determine that the first and second music data files are layered; and
simultaneously play back the modified version of the first music data file and a modified version of the second music data file, wherein the playback includes ending the playback of the second music data file when the cut threshold of the tail portion of the first music data file is reached.
